(19) United States
(12) Patent Application Publication
(10) Pub. No.: US 2025/0123303 A1
(43) Pub. Date: Apr. 17, 2025

(54) INTEGRATED PROCESS FLOW FOR SENSOR PACKAGE

(71) Applicant: Taiwan Semiconductor Manufacturing Company, Ltd., Hsinchu (TW)

(72) Inventors: Chia-Hua Chu, Zhubei City (TW); Chun-Wen Cheng, Zhubei City (TW)

(21) Appl. No.: 18/486,211

(22) Filed: Oct. 13, 2023

(51) Int. Cl. G01P 15/09; H10N 39/00

(52) U.S. Cl. CPC G01P 15/09; H10N 39/00

(57) ABSTRACT

In some embodiments, the present disclosure relates to an integrated device, including: a substrate; a semiconductor layer on the substrate and including a first structure being one of a sound port, a sealed cavity, or a proof mass, and a second structure being one of the sound port, the sealed cavity, or the proof mass, where the second structure is a different one of the sound port, the sealed cavity, or the proof mass than the first structure; a piezoelectric layer on the semiconductor layer overlying the first structure and the second structure; and an air gap extending into the semiconductor layer from an upper surface of the piezoelectric layer, wherein the first structure and portions of the piezoelectric layer overlying the first structure are spaced from the second structure and portions of the piezoelectric layer overlying the second structure by the air gap.

### BACKGROUND

Many modern day electronic devices include sensors. Sensors capable of detecting sound, pressure, and acceleration may be used for a wide variety of purposes. Some devices contain multiple different types of sensors and use them to gather a variety of different types of data. Some sensors utilize piezoelectric materials to convert strain of the piezoelectric material into electric signals. The electric signals are sometimes sent to application specific integrated circuits (ASICs).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C illustrate a cross-sectional view and a top view of some embodiments of an integrated chip having a piezoelectric micromachined ultrasonic transducer (PMUT), a pressure sensor, and an accelerometer on a common substrate.

FIG. 2 illustrates a cross-sectional view of some embodiments of a package holding an integrated chip having the PMUT, the pressure sensor, and the accelerometer on the substrate.

FIGS. 3A-3E illustrate cross-sectional views of some additional embodiments of an integrated chip having two or more sensors in a semiconductor layer on the substrate.

FIGS. 4-19 illustrate cross-sectional views of some embodiments of a method of forming an integrated chip having the PMUT, the pressure sensor, and the accelerometer on the substrate.

FIG. 20 illustrates a flow diagram of some embodiments of a method of forming an integrated chip having two or more sensors on the substrate separated by an air gap.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Sensors are used to acquire a variety of different data in integrated devices. In some devices, multiple different kinds of sensors may be used to perform the full functionality expected from the device. Some devices accomplish this by including multiple different sensor chips in one package. The different sensor chips are connected to different ASICs by using wire bonds. However, the plurality of wire bonds introduce parasitic electrical effects (e.g., parasitic capacitance and parasitic resistance) between the wire bonds, sensor chips, and integrated circuits. Also, as devices and products are expected to grow smaller by consumers, the ability to include multiple sensor chips in one package may be constrained by the space available in the device. Forming multiple sensors on one chip may reduce the number of wire bonds used and may reduce the space used by the sensor chips, though using the individual process flows of the separate chip designs may be prohibitively expensive.

The present disclosure provides an integrated process flow to form multiple different sensors on one chip. The sensors are formed by forming a plurality of insulative layers within a semiconductor layer. A piezoelectric layer is formed over the semiconductor layer to convert strain caused by the sensors into an electrical signal. The plurality of insulative layers are used as sacrificial layers and etch stop layers in the formation of two or more structures. The two or more structures combined with the piezoelectric layer comprise two or more different sensors overlying a common substrate. Further, air gaps between the two or more sensors mitigate interference due to the motion of the two or more structures. As the formation of the insulative layers, the piezoelectric layer and the semiconductor layer are all processes shared by the different sensors, the presented method reduces the number of steps necessary to form multiple sensors on one substrate. Further, the chip with multiple sensors may reduce the testing cost compared to an integrated device with multiple separate sensor chips, as the number chips to be tested is reduced.

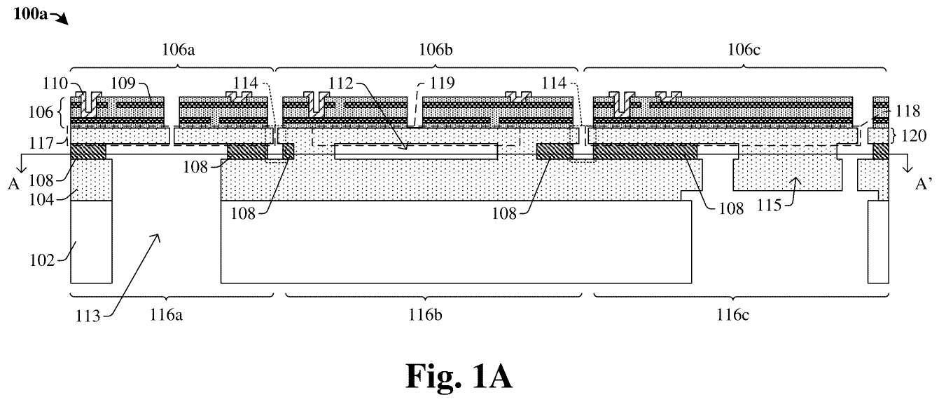

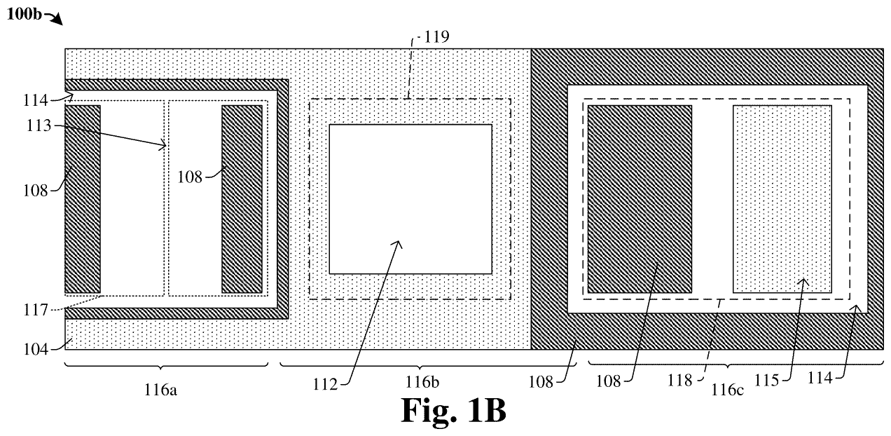

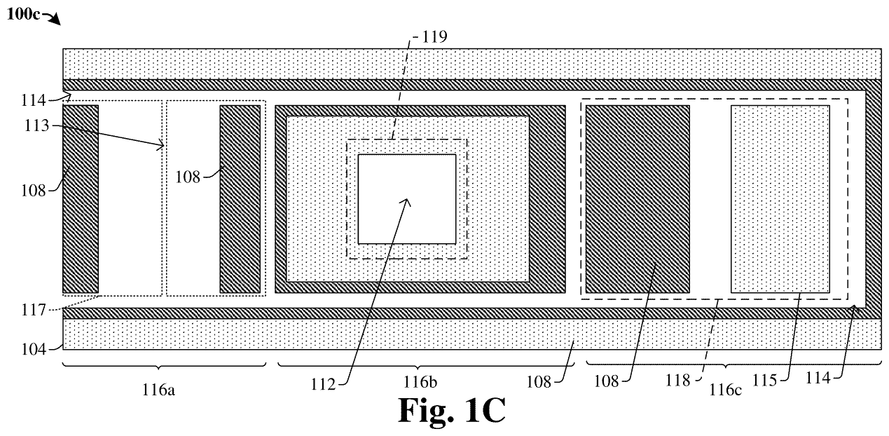

FIGS. 1A-1C illustrate a cross-sectional view 100a and top views 100b, 100c of some embodiments of an integrated chip having a piezoelectric micromachined ultrasonic transducer (PMUT), a pressure sensor, and an accelerometer on a common substrate. The top views 100b, 100c of FIGS. 1B and 1C may, for example, be taken along line A-A′ in FIG. 1A.

A semiconductor layer 104 overlies a substrate 102. A piezoelectric layer 106 is on the semiconductor layer 104. Two or more sensors 116a-116c are integrated into the semiconductor layer 104 and the piezoelectric layer 106. In some embodiments, the two or more sensors 116a-116c comprise a piezoelectric micromachined ultrasonic transducer (PMUT) 116a, a pressure sensor 116b, and an accelerometer 116c. In other embodiments, the two or more sensors 116a-116c comprise two different sensors of the PMUT 116a, the pressure sensor 116b, and/or the accelerometer 116c. The two or more sensors 116a-116c individually comprise a moving structure of two or more moving structures 120 and a portion of the piezoelectric layer 106 overlying the moving structure. In some embodiments, the two or more moving structures 120 comprise one or more arms 117 within the PMUT 116a, a first arm 118 within the accelerometer 116c, and a cap 119 within the pressure sensor 116b.

The PMUT 116a comprises a sound port 113, one or more arms 117 and a first portion 106a of the piezoelectric layer 106 overlying the one or more arms 117. The pressure sensor 116b comprises a sealed cavity 112, a cap 119 overlying the sealed cavity 112, and a second portion of the piezoelectric layer 106b overlying the cap 119. The accelerometer 116c comprises a proof mass 115, a first arm 118, and a third portion 106c of the piezoelectric layer 106 overlying the first arm 118. A microphone may also extend as one or more arms over the sound port 113 in addition to or instead of the PMUT 116a. Embodiments described hereafter comprising the PMUT 116a may also comprise a microphone extending over the sound port 113.

In some embodiments, the one or more arms 117 of the PMUT 116a and the first arm 118 of the accelerometer 116c are separated from the semiconductor layer 104 by a plurality of insulative columns 108. In some embodiments, the plurality of insulative columns 108 further space the PMUT 116a and the accelerometer 116c from the sealed cavity 112.

The two or more moving structures 120 are separated by air gaps 114. The air gaps 114 are configured to reduce interference between the two or more moving structures 120, reducing noise in signals emitted by the two or more sensors 116a-116c. The air gaps 114 have a first region with a first width extending directly between the two or more moving structures 120 and a second region with a second width extending below the first region. The second region is level with the insulative columns 108, and exposes sidewalls of the insulative columns 108. The first width is less than the second width. In some embodiments, the first width is between 2 micrometers and 100 micrometers, between 2.5 micrometers and 90 micrometers, between 3 micrometers and 60 micrometers, or the like. A plurality of wires 109 are embedded in the piezoelectric layer 106, and a plurality of contacts 110 are coupled to the plurality of wires 109 and past outer surfaces of the piezoelectric layer 106.

As shown in the top view 100b of FIG. 1B, the one or more arms 117 and the first arm 118 are isolated from the semiconductor layer 104 by air gaps 114. The isolation of the one or more arms 117 and the first arm 118 results in a greater degree of motion that may be used to measure the incoming sound waves or the acceleration of the device. The greater degree of motion further results in the first and third portions (see 106a, 106c of FIG. 1A) of the piezoelectric layer (see 106 of FIG. 1A) being subjected to a higher amount of strain, resulting in a stronger signal being output from the two or more sensors 116a-116c. Further, the one or more arms are separated from one another by an air gap. As shown in the top view 100c of FIG. 1C, a portion of the semiconductor layer containing the pressure sensor 116b may be separated from the rest of the semiconductor layer 104 by air gaps 114 that continuously encircle the portion containing the pressure sensor 116b.

The integration of the two or more sensors 116a-116c onto the substrate 102 reduces the amount of space the sensors in a finished product will occupy, increasing the number of applications that the sensors can be applied to. Integration of the two or more sensors 116a-116c onto the substrate 102 also results in a cost reduction in applications where the sensors would be used, as one sensor chip can be formed and used instead of two or more. The additional steps added to the process flow to form two or more sensors 116a-116c on the same substrate 102 are significantly lower cost than the cost of forming two individual sensor chips for the same application. Devices using multiple separate chips also independently test the separate chips, using different tests and potentially multiple testing environments, whereas a sensor chip with two or more sensors 116a-116c may reduce the number of tests to run, further reducing costs.

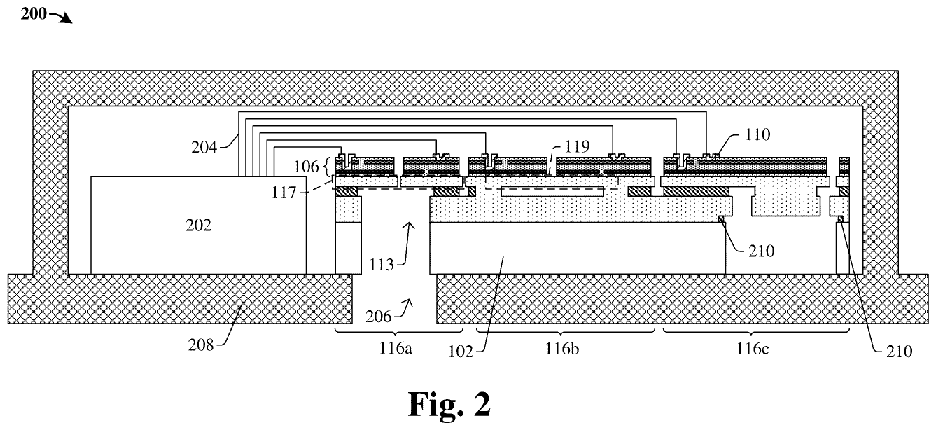

FIG. 2 illustrates a cross-sectional view 200 of some embodiments of a package holding an integrated chip having the PMUT, the pressure sensor, and the accelerometer on the substrate.

A package 208 surrounds the substrate 102, and further surrounds an application specific integrated circuit (ASIC) 202. The ASIC 202 is coupled to the contacts 110 in the piezoelectric layer 106 by a plurality of wire bonds 204. The ASIC 202 is configured to read and process the signals emitted by the two or more sensors 116a-116c. In designs where multiple separate sensor chips are used, multiple separate ASIC chips are also used to read and process the signals from the sensors. The two or more sensors 116a-116c on the substrate 102 may be coupled to the ASIC 202, which may contain the circuitry used to read and process the signals from the two or more sensors 116a-116c, reducing the number of ASIC chips used and further reducing the minimum size of the package. In some embodiments, second insulative columns 210 are on the substrate 102 beneath the accelerometer 116c.

The package 208 comprises a port 206. In some embodiments, wherein one of the two or more sensors 116a-116c is the PMUT 116a, the port 206 is directly beneath the sound port 113 extending through the substrate 102. That is, the port 206 and the sound port 113 are centered on an axis that extends through the port 206 and the sound port 113. The alignment of the port 206 and the sound port 113 results in the sound port 113 directly receiving mechanical waves transmitted in the ambient environment outside of the package 208, improving the sensitivity of the PMUT 116a. In embodiments comprising the pressure sensor 116b and/or the accelerometer 116c, the pressure sensor 116b and the accelerometer 116c are offset from the port 206 to mitigate the effects of the mechanical waves on the signals emitted by the pressure sensor 116b and/or the accelerometer 116c.

Further, the port 206 being directly beneath the sound port 113 results in both improved sensitivity for the PMUT 116a while also forming a path through the sound port 113 and the air gap between one or more arms that couples the inside of the package 208 to the ambient environment outside the package 208. The coupling of the inside of the package to the outside of the package results in the pressure sensor 116b having the sealed cavity 112 on one side of the cap 119 and a region coupled to the ambient environment on the opposite side of the cap 119. The configuration described results in more accurate readings for the pressure sensor 116b, as the air pressure inside the package 208 is substantially the same as the air pressure in the ambient environment, without using more than one port 206 in the package 208.

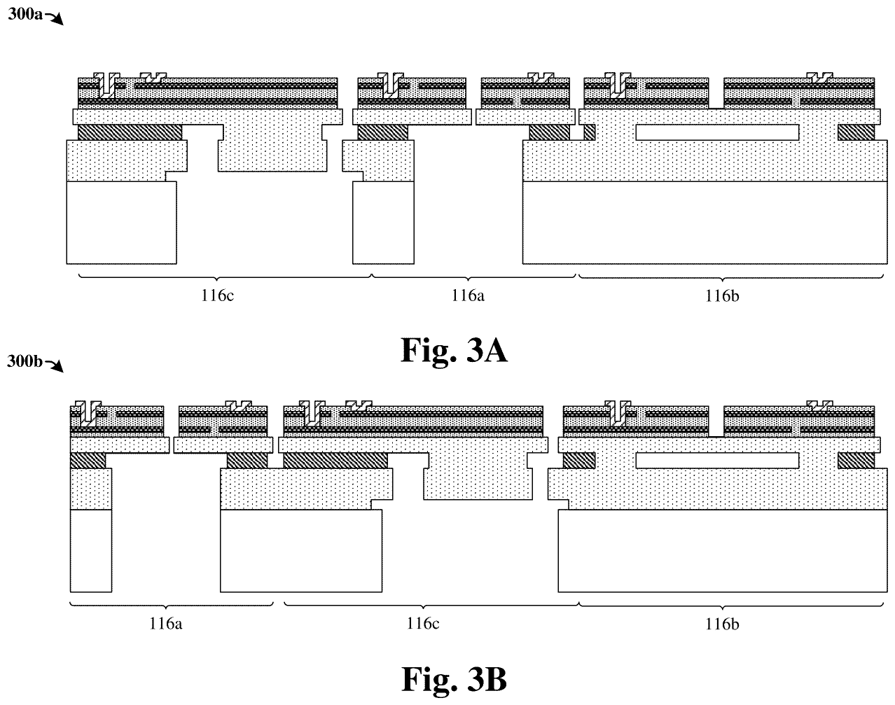

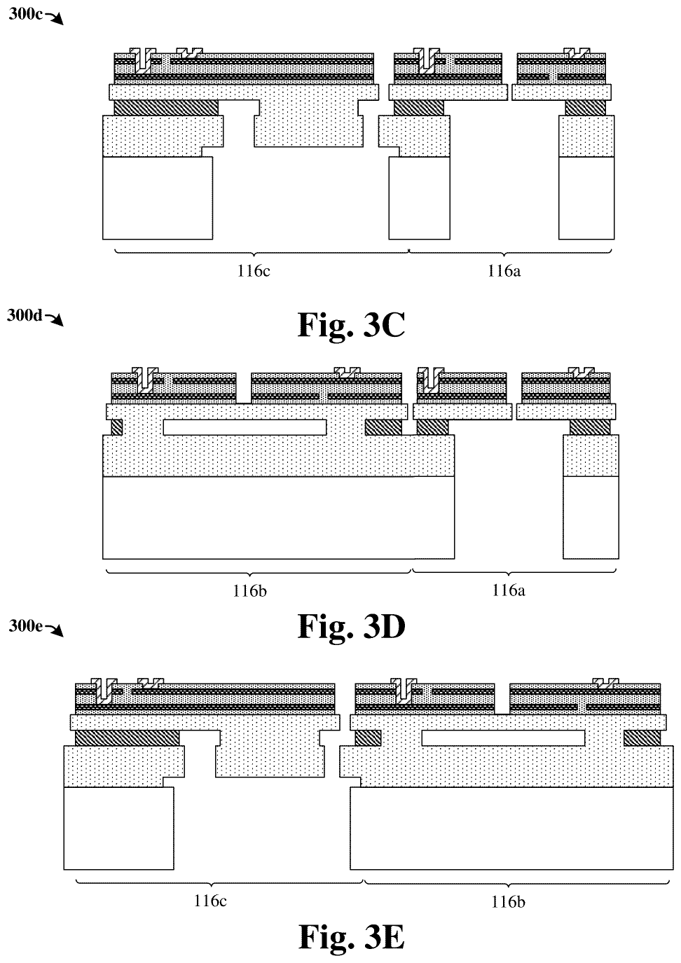

FIGS. 3A-3E illustrate cross-sectional views 300a-300e of some additional embodiments of an integrated chip having two or more sensors in a semiconductor layer on the substrate.

In some embodiments, as shown in the cross-sectional views 300a. 300b of FIGS. 3A and 3B, the two or more sensors 116a-116c may comprise the PMUT 116a, the pressure sensor 116b, and the accelerometer 116c arranged in any order. For example, the PMUT 116a may be between the accelerometer 116c and the pressure sensor 116b as shown in FIG. 3A, or the accelerometer 116c may be between the PMUT 116a and the pressure sensor 116b, as shown in FIG. 3B. In some embodiments, the two or more sensors 116a-116c are not arranged linearly. For example, a first sensor (e.g., the PMUT 116a) may be offset from a second sensor (e.g., the pressure sensor) in a first direction, and a third sensor (e.g., the accelerometer 116c) may be offset from the second sensor in a second direction perpendicular to the first direction.

In some embodiments, as shown in the cross-sectional views 300c, 300d, 300e of FIGS. 3C, 3D, and 3E, the two or more sensors 116a-116c may comprise two different sensors (e.g., the PMUT 116a, the pressure sensor 116b, or the accelerometer 116c) in any combination. For example, the two or more sensors 116a-116c may be the PMUT 116a and the accelerometer 116c (as shown in FIG. 3C), the pressure sensor 116b and the PMUT 116a (as shown in FIG. 3D), or the pressure sensor 116b and the accelerometer 116c (as shown in FIG. 3E). The embodiments shown in FIGS. 3C, 3D, and 3E further reduce the amount of space taken by the package in applications where one of the two or more sensors 116a-116c are not used.

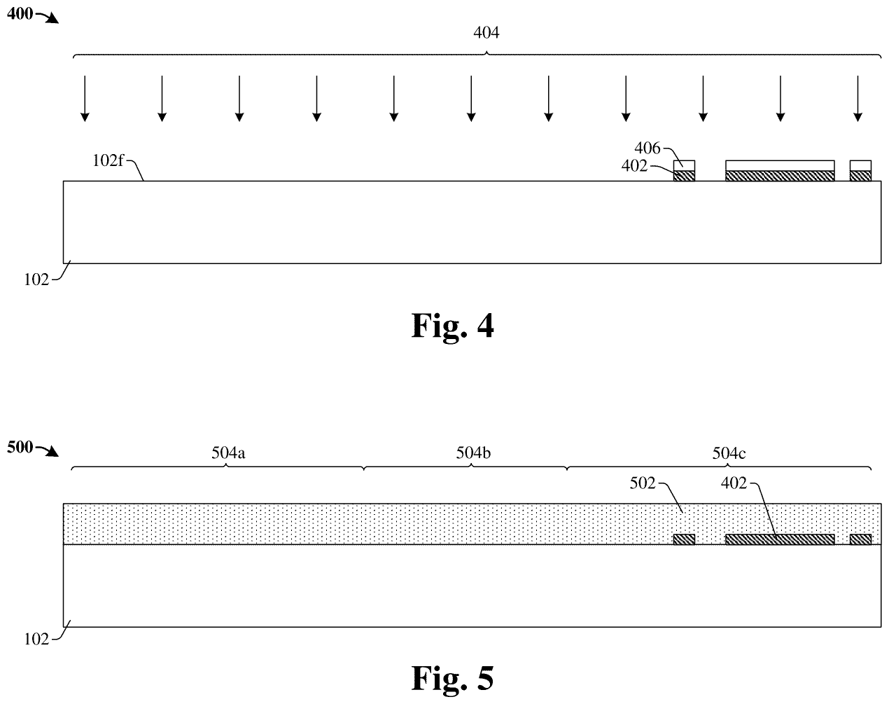

FIGS. 4-19 illustrate cross-sectional views 400-1900 of some embodiments of a method of forming an integrated chip having the PMUT, the pressure sensor, and the accelerometer on the substrate. Although FIGS. 4-19 are described in relation to a method, it will be appreciated that the structures disclosed in FIGS. 4-19 are not limited to such a method, but instead may stand alone as structures independent of the method.

As shown in a cross-sectional view 400 of FIG. 4, the substrate 102 is provided. A first sacrificial layer 402 is formed on the substrate 102. The first sacrificial layer 402 is formed by depositing a first conformal sacrificial layer over a first side 102f of the substrate 102. In some embodiments, the first conformal sacrificial layer is formed using one of chemical vapor deposition (CVD), physical vapor deposition (PVD), atomic layer deposition (ALD), some other suitable deposition process, or a combination of the foregoing. In some embodiments, the first conformal sacrificial layer is or comprises an oxide (e.g., SiO₂) or the like. The first conformal sacrificial layer is then covered by a first masking layer 406, which is then patterned. In some embodiments, the first masking layer 406 is or comprises a hard mask, a photoresist, or the like.

After the first masking layer 406 is patterned, a first etching process 404 is performed, removing portions of the first conformal sacrificial layer that are exposed by the first masking layer 406 and leaving the first sacrificial layer 402. In some embodiments, the first etching process 404 is a dry etching process (e.g., a plasma etch). The first masking layer 406 is then removed, leaving the first sacrificial layer 402 on the substrate 102.

As shown in a cross-sectional view 500 of FIG. 5, a first semiconductor layer 502 is formed over the substrate 102 and the first sacrificial layer 402. The first semiconductor layer 502 has a first portion 504a, and a second portion 504b. In further embodiments, the first semiconductor layer 502 additionally comprises a third portion 504c. In some embodiments, the first sacrificial layer 402 is within one of the first portion 504a, the second portion 504b, or the third portion 504c. In some embodiments, the first semiconductor layer 502 is or comprises polysilicon or the like. The first semiconductor layer 502 is formed using one of epitaxy, a deposition process, such as CVD, PVD, ALD, some other suitable deposition process, or a combination of the foregoing. After the first semiconductor layer 502 is formed, a planarization process (e.g., a chemical mechanical planarization (CMP) process) is performed, resulting in the first semiconductor layer 502 having a substantially flat upper surface.

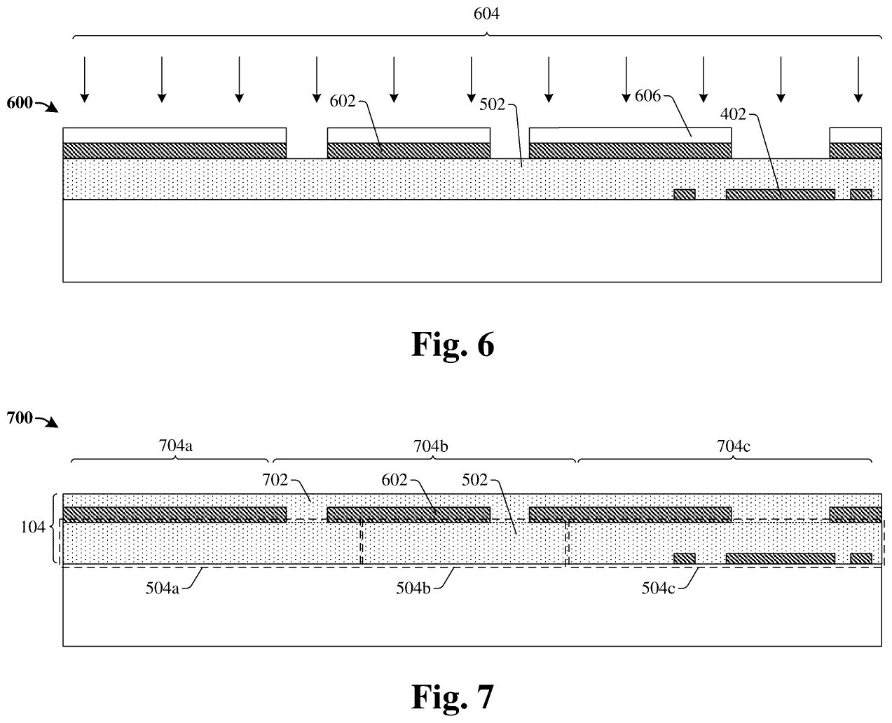

As shown in a cross-sectional view 600 of FIG. 6, a second sacrificial layer 602 is formed on the first semiconductor layer 502. The second sacrificial layer 602 is formed by depositing a second conformal sacrificial layer over the first semiconductor layer 502. In some embodiments, the second conformal sacrificial layer is formed using one of CVD, PVD, ALD, some other suitable deposition process, or a combination of the foregoing. In some embodiments, the second conformal sacrificial layer is or comprises an oxide (e.g., SiO₂) or the like. The second conformal sacrificial layer is then covered by a second masking layer 606, which is then patterned. In some embodiments, the second masking layer 606 is or comprises a hard mask, a photoresist, or the like.

After the second masking layer 606 is patterned, a second etching process 604 is performed, removing portions of the second conformal sacrificial layer that are exposed by the second masking layer 606. In some embodiments, the second etching process 604 is a dry etching process (e.g., a plasma etch). The second masking layer 606 is then removed, leaving the second sacrificial layer 602 on the first semiconductor layer 502. In some embodiments, the second sacrificial layer 602 has an opening over a central portion of the first sacrificial layer 402.

As shown in a cross-sectional view 700 of FIG. 7, a second semiconductor layer 702 is formed over the first semiconductor layer 502 and the second sacrificial layer 602. The second semiconductor layer 702 has a first portion 704a, and a second portion 704b. In further embodiments, the second semiconductor layer 702 additionally comprises a third portion 704c. The first portion 704a, the second portion 704b and the third portion 704c are respectively directly above the first portion 504a, the second portion 504b, and the third portion 504c of the first semiconductor layer 502. In some embodiments, the second semiconductor layer 702 is or comprises polysilicon or the like. The second semiconductor layer 702 is formed using one of epitaxy, a deposition process, such as CVD, PVD, ALD, some other suitable deposition process, or a combination of the foregoing. After the second semiconductor layer 702 is formed, a planarization process (e.g., a chemical mechanical planarization (CMP) process) is performed, resulting in the second semiconductor layer 702 having a substantially flat upper surface. The first semiconductor layer 502 and the second semiconductor layer 702 together form the semiconductor layer 104. In some embodiments, the semiconductor layer 104 is or comprises one of silicon (Si), silicon-germanium (SiGe), or the like.

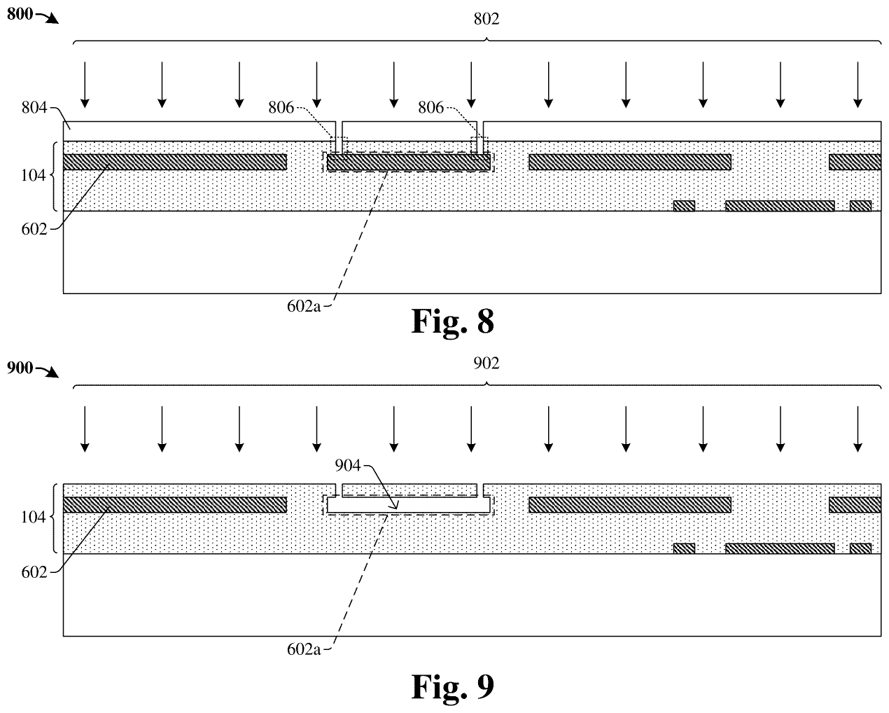

As shown in a cross-sectional view 800 of FIG. 8, a third etching process 802 is performed on the semiconductor layer 104 according to the pattern of a third masking layer 804. In some embodiments, the third etching process 802 is a dry etching process (e.g., a plasma etch). The third etching process 802 results in a plurality of trenches 806 extending to a first portion 602a of the second sacrificial layer 602 within a region of the integrated device. The region of the integrated device is one where the sealed cavity 112 is to be formed in the process of forming a pressure sensor 116b.

As shown in a cross-sectional view 900 of FIG. 9, a fourth etching process 902 is performed on the semiconductor layer 104, whereby the first portion 602a of the second sacrificial layer 602 is removed. In some embodiments, the fourth etching process 902 is a wet etching process or a vapor etching process configured to etch the material of the second sacrificial layer 602 at a greater rate than the material of the semiconductor layer 104. The fourth etching process 902 results in an unsealed cavity 904 within the semiconductor layer 104.

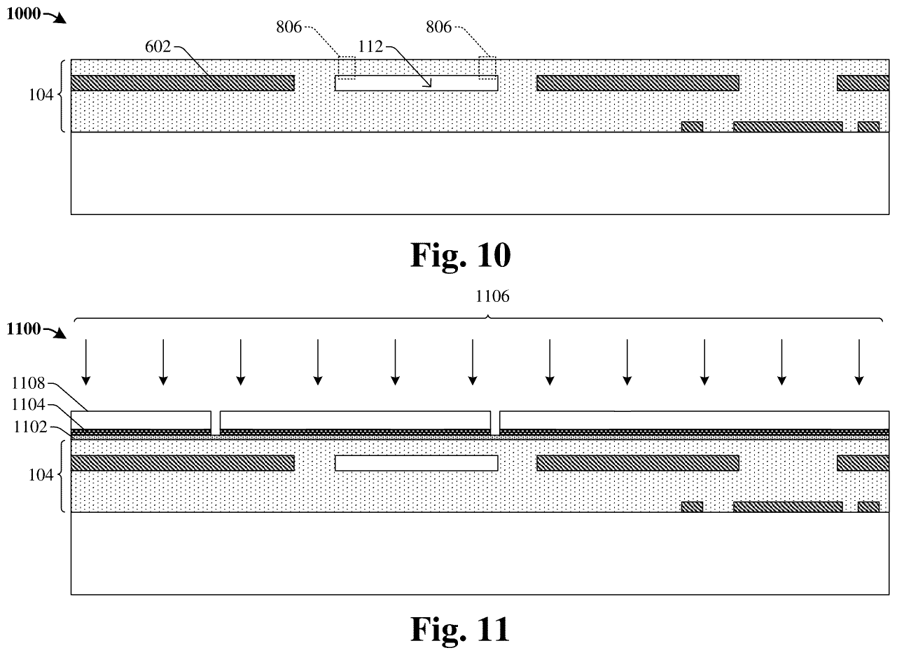

As shown in a cross-sectional view 1000 of FIG. 10, the sealed cavity 112 is formed. The sealed cavity 112 is formed using a conformal deposition of a same material as the semiconductor layer 104, filling the plurality of trenches 806. In some embodiments, the conformal deposition is or comprises one of CVD, PVD, ALD, some other suitable deposition process, or a combination of the foregoing. In some embodiments, the conformal deposition process partially fills the sealed cavity 112 as it is sealed, resulting in the sealed cavity 112 having a thickness that is less than a thickness of the second sacrificial layer 602. In some embodiments, the sealed cavity 112 has a pressure between 1 and 1000 mTorr, or the like.

As shown in a cross-sectional view 1100 of FIG. 11, a first piezoelectric layer 1102 and a first conductive layer 1104 are formed over the semiconductor layer 104. The first piezoelectric layer 1102 and the first conductive layer 1104 are individually formed using a deposition process comprising one of CVD, PVD, ALD, some other suitable deposition process, or a combination of the foregoing. After the first conductive layer 1104 is deposited, it is patterned. The patterning of the first conductive layer 1104 is performed using a fifth etching process 1106 and a fourth masking layer 1108. The fourth masking layer 1108 is or comprises a hard mask or photoresist, and in some embodiments is patterned using an additional etching step or photolithography. In some embodiments, the fifth etching process 1106 is a dry etch (e.g., a plasma dry etch). The fourth masking layer 1108 is then removed.

As shown in a cross-sectional view 1200 of FIG. 12, a second piezoelectric layer 1202 and a second conductive layer 1204 are formed over the first piezoelectric layer 1102 and the first conductive layer 1104. The second piezoelectric layer 1202 and the second conductive layer 1204 are individually formed using a deposition process comprising one of CVD, PVD, ALD, some other suitable deposition process, or a combination of the foregoing. After the second conductive layer 1204 is deposited, it is patterned. The patterning of second conductive layer 1204 is performed using a sixth etching process 1206 and a fifth masking layer 1208. The fifth masking layer 1208 is or comprises a hard mask or photoresist, and in some embodiments is patterned using an additional etching step or photolithography. In some embodiments, the sixth etching process 1206 is a dry etch (e.g., a plasma dry etch). The fifth masking layer 1208 is then removed. The first conductive layer 1104 and the second conductive layer 1204 together form the plurality of wires 109.

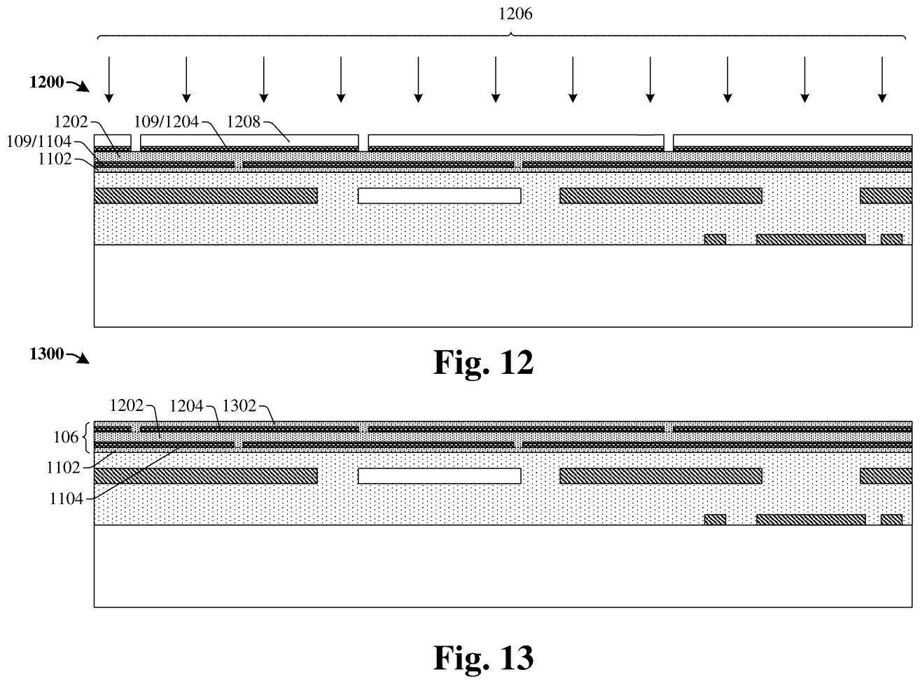

As shown in a cross-sectional view 1300 of FIG. 13, a third piezoelectric layer 1302 is formed, covering the second conductive layer 1204. The first piezoelectric layer 1102, the second piezoelectric layer 1202, and the third piezoelectric layer 1302 together form the piezoelectric layer 106. In some embodiments, the piezoelectric layer 106 is or comprises one of aluminum nitride (AlN), scandium doped aluminum nitride (ScAIN), lead zirconium titanate (PZT), or the like. In some embodiments, the first conductive layer 1104 and the second conductive layer 1204 are or comprise molybdenum (Mo), gold (Au), platinum (Pt), or the like.

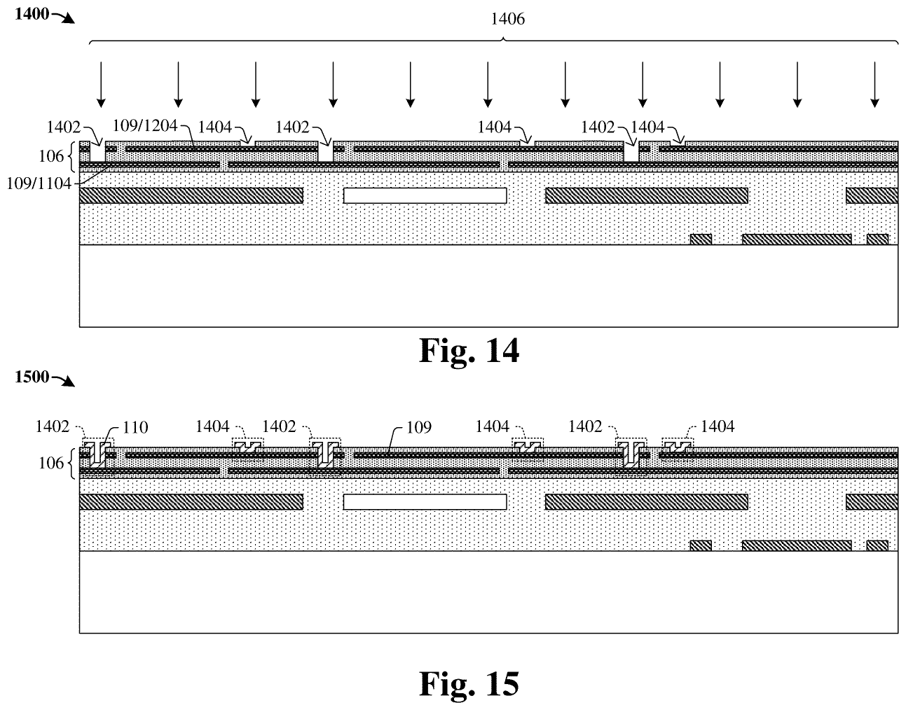

As shown in a cross-sectional view 1400 of FIG. 14, a plurality of etching processes 1406 are performed, resulting in a first plurality of openings 1402 and a second plurality of openings 1404 extending into the piezoelectric layer 106. The first plurality of openings 1402 extend to the first conductive layer 1104 of the plurality of wires 109, and the second plurality of openings 1404 extend to the second conductive layer 1204 of the plurality of wires 109.

As shown in a cross-sectional view 1500 of FIG. 15, a plurality of contacts 110 are formed in the first plurality of openings 1402 and the second plurality of openings 1404. The plurality of contacts 110 are formed by depositing a conformal conductive layer over the piezoelectric layer 106, and then patterning the conformal conductive layer to remove portions of the conformal conductive layer outside of the plurality of contacts 110. In some embodiments, the plurality of contacts 110 are or comprise an aluminum-copper alloy (AlCu), another conductive material, or the like. The plurality of contacts 110 are coupled to the plurality of wires 109.

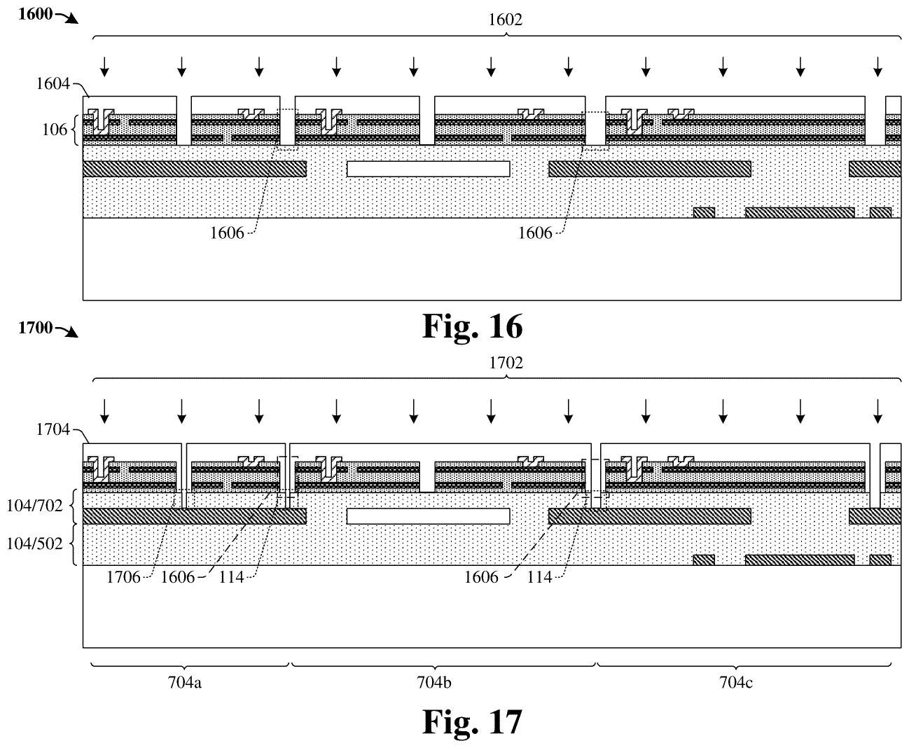

As shown in the cross-sectional view 1600 of FIG. 16, a sixth masking layer 1604 is formed over the piezoelectric layer 106. The sixth masking layer 1604 comprises a hard mask or a photoresist. The sixth masking layer 1604 is then patterned. A seventh etching process 1602 is performed to pattern the piezoelectric layer 106 after the sixth masking layer 1604 is patterned. The seventh etching process 1602 etches through the piezoelectric layer 106, forming second openings 1606 and exposing the semiconductor layer 104.

As shown in the cross-sectional view 1700 of FIG. 17, a seventh masking layer 1704 is formed over the piezoelectric layer 106. The seventh masking layer 1704 comprises a hard mask or a photoresist. The seventh masking layer 1704 is then patterned. An eighth etching process 1702 is performed to pattern the second semiconductor layer 702 beneath the second openings 1606 after the seventh masking layer 1704 is patterned, forming the air gaps 114. The eighth etching process 1702 etches into the semiconductor layer 104, exposing portions of the second sacrificial layer 602 between the first portion 704a and the second portion 704b, and between the second portion and the third portion 704c of the second semiconductor layer. In some embodiments, the eighth etching process 1702 further forms an additional air gap 1706 within the first portion 704a.

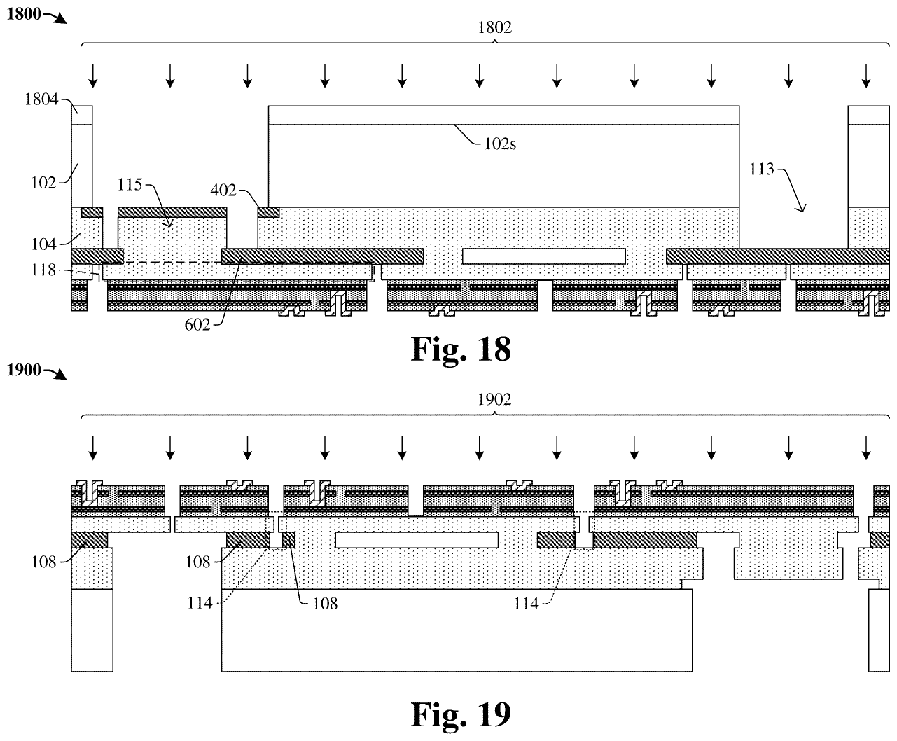

As shown in the cross-sectional view 1800 of FIG. 18, an eighth masking layer 1804 is formed and patterned over a second side 102s of the substrate 102. A ninth etching process 1802 is then performed, removing portions of the substrate 102 and the semiconductor layer 104 corresponding to the sound port 113 and surrounding the proof mass 115. The ninth etching process further exposes portions of the first sacrificial layer 402 and the second sacrificial layer 602. In some embodiments, the ninth etching process is one or more dry etching processes (e.g., plasma dry etching). The first sacrificial layer 402 covers a bottom surface of the proof mass 115, preventing the proof mass 115 from being etched. Further, the second sacrificial layer 602 covers a bottom surface of the first arm 118, preventing the first arm from being etched.

As shown in the cross-sectional view 1900 of FIG. 19, a tenth etching process 1902 is performed on the integrated device, removing exposed portions of the second sacrificial layer (see 602 of FIG. 18) and the first sacrificial layer (see 402 of FIG. 18). The tenth etching process 1902 is configured to remove the first sacrificial layer (see 402 of FIG. 18) while only partially removing the second sacrificial layer (see 602 of FIG. 18), leaving the insulative columns 108 in the semiconductor layer 104. In some embodiments, portions of the first sacrificial layer (see 402 of FIG. 18) remain as second insulative columns (see 210 of FIG. 2) after the tenth etching process 1902. The tenth etching process 1902 expands the air gaps 114, resulting in the air gaps 114 having a wide portion level with the insulative columns 108 and a narrow portion separating the wide portion from a surface of the semiconductor layer 104.

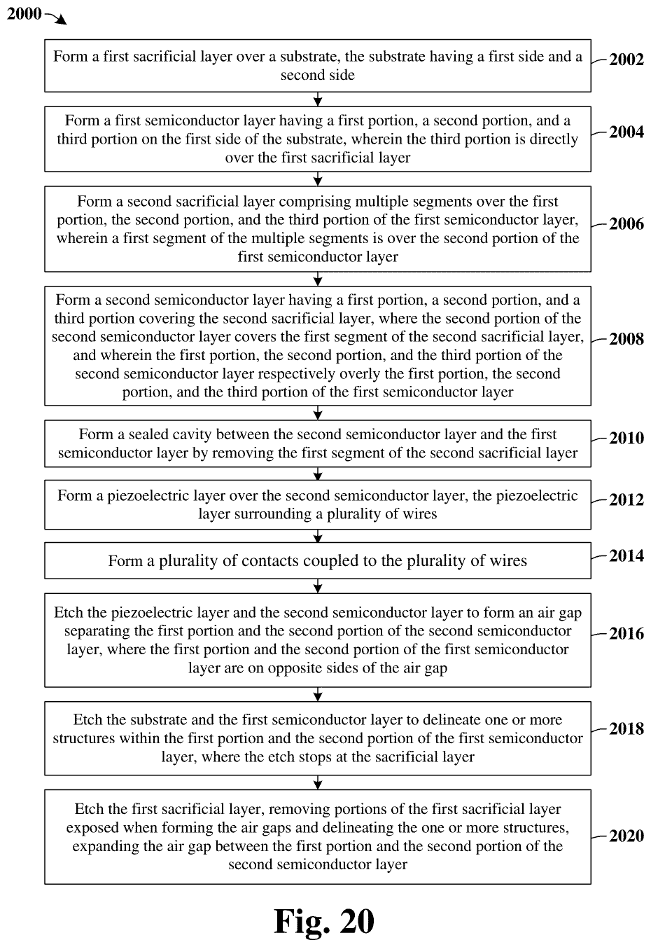

FIG. 20 illustrates a flow diagram 2000 of some embodiments of a method of forming an integrated chip having two or more sensors on a substrate separated by an air gap.

While the method is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 2002, a first sacrificial layer over a substrate, the substrate having a first side and a second side. FIG. 4 illustrates a cross-sectional view 400 of some embodiments corresponding to act 2002.

At 2004, a first semiconductor layer having a first portion, a second portion, and a third portion is formed on the first side of the substrate, wherein the third portion is directly over the first sacrificial layer. FIG. 5 illustrates a cross-sectional view 500 of some embodiments corresponding to act 2004.

At 2006, a second sacrificial layer comprising multiple segments is formed over the first portion, the second portion, and the third portion of the first semiconductor layer, wherein a first segment of the multiple segments is over the second portion of the first semiconductor layer. FIG. 6 illustrates a cross-sectional view 600 of some embodiments corresponding to act 2006.

At 2008, a second semiconductor layer having a first portion, a second portion, and a third portion is formed, the second semiconductor layer covering the second sacrificial layer, where the second portion of the second semiconductor layer covers the first segment of the second sacrificial layer, and wherein the first portion, the second portion, and the third portion of the second semiconductor layer respectively overly the first portion, the second portion, and the third portion of the first semiconductor layer. FIG. 7 illustrates a cross-sectional view 700 of some embodiments corresponding to act 2008.

At 2010, a sealed cavity is formed between the second semiconductor layer and the first semiconductor layer by removing the first segment of the second sacrificial layer. FIGS. 8-10 illustrate cross-sectional views 800-1000 of some embodiments corresponding to act 2010.

At 2012, a piezoelectric layer is formed over the second semiconductor layer, the piezoelectric layer surrounding a plurality of wires. FIGS. 11-13 illustrate cross-sectional views 1100-1300 of some embodiments corresponding to act 2012.

At 2014, a plurality of contacts are formed coupling to the plurality of wires. FIGS. 14-15 illustrate cross-sectional views 1400-1500 of some embodiments corresponding to act 2014.

At 2016, the piezoelectric layer and the second semiconductor layer are etched to form air gaps separating the first portion, the second portion, and the third portion of the second semiconductor layer, exposing the second sacrificial layer. FIGS. 16-17 illustrate cross-sectional views 1600-1700 of some embodiments corresponding to act 2016.

At 2018, the substrate and the first semiconductor layer are etched from a second side of the substrate to delineate one or more structures within the first portion and the third portion of the first semiconductor layer, where the etching stops at the first sacrificial layer and the second sacrificial layer. FIG. 18 illustrates a cross-sectional view 1800 of some embodiments corresponding to act 2018.

At 2020, the first sacrificial layer and the second sacrificial layer are etched, removing portions of the first sacrificial layer and the second sacrificial layer exposed when forming the air gaps and delincating the one or more structures, expanding the air gap between the first portion, the second portion, and the third portion of the second semiconductor layer. FIG. 19 illustrates a cross-sectional view 1900 of some embodiments corresponding to act 2020.

Therefore, the present disclosure relates to a new method of forming an integrated chip having two or more sensors on a substrate separated by an air gap.

Accordingly, in some embodiments, the present disclosure relates to an integrated device, including: a substrate; a semiconductor layer on the substrate and including a first structure being one of a sound port, a sealed cavity, or a proof mass, and a second structure being one of the sound port, the sealed cavity, or the proof mass, where the second structure is a different one of the sound port, the sealed cavity, or the proof mass than the first structure; a piezoelectric layer on the semiconductor layer overlying the first structure and the second structure; and an air gap extending into the semiconductor layer from an upper surface of the piezoelectric layer, wherein the first structure and portions of the piezoelectric layer overlying the first structure are spaced from the second structure and portions of the piezoelectric layer overlying the second structure by the air gap.

In other embodiments, the present disclosure relates to an integrated device, including a substrate having a first portion and a second portion; a first sensor on the first portion of the substrate, the first sensor having a first moving structure being one of a first arm coupled to a proof mass, a cap overlying a sealed cavity, or one or more arms overlying a sound port extending through the substrate; a second sensor on the second portion of the substrate, the second sensor having a second moving structure being one of the first arm coupled to the proof mass, the cap overlying a sealed cavity, or the one or more arms overlying the sound port extending through the substrate, the second moving structure being different from the first moving structure; an application specific integrated circuit (ASIC) configured to receive first and second signals from the first sensor and the second sensor, respectively; and a package surrounding the substrate and the ASIC, the package having a port connecting an inner region of the package to an ambient environment outside the package.

In yet other embodiments, the present disclosure relates to a method of forming an integrated device, including forming a first sacrificial layer over a substrate, the substrate having a first side and a second side; forming a first semiconductor layer having a first portion, a second portion, and a third portion on the first side of the substrate, where the third portion is directly over the first sacrificial layer; forming a second sacrificial layer comprising multiple segments over the first portion, the second portion, and the third portion of the first semiconductor layer, wherein a first segment of the multiple segments is over the second portion of the first semiconductor layer; forming a second semiconductor layer having a first portion, a second portion, and a third portion covering the second sacrificial layer, where the second portion of the second semiconductor layer covers the first segment of the second sacrificial layer, and where the first portion, the second portion, and the third portion of the second semiconductor layer respectively overly the first portion, the second portion, and the third portion of the first semiconductor layer; forming a sealed cavity between the second semiconductor layer and the first semiconductor layer by removing the first segment of the second sacrificial layer; forming a piezoelectric layer over the second semiconductor layer, the piezoelectric layer surrounding a plurality of wires; forming a plurality of contacts coupled to the plurality of wires; etching the piezoelectric layer and the second semiconductor layer to form air gaps separating the first portion, the second portion, and the third portion of the second semiconductor layer, exposing the second sacrificial layer; etching the substrate and the first semiconductor layer from a second side of the substrate to delineate one or more structures within the first portion and the third portion of the first semiconductor layer, where the etching stops at the first sacrificial layer and the second sacrificial layer; and etching the first sacrificial layer and the second sacrificial layer, removing portions of the first sacrificial layer and the second sacrificial layer exposed when forming the air gaps and delineating the one or more structures, expanding the air gap between the first portion, the second portion, and the third portion of the second semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a substrate;
a semiconductor layer on the substrate and comprising a first structure being one of a sound port, a sealed cavity, or a proof mass, and a second structure being one of the sound port, the sealed cavity, or the proof mass, where the second structure is a different one of the sound port, the sealed cavity, or the proof mass than the first structure;
a piezoelectric layer on the semiconductor layer overlying the first structure and the second structure; and
an air gap extending into the semiconductor layer from an upper surface of the piezoelectric layer, wherein the first structure and portions of the piezoelectric layer overlying the first structure are spaced from the second structure and portions of the piezoelectric layer overlying the second structure by the air gap.

2. The integrated device of claim 1, further comprising:
insulative columns within the semiconductor layer, wherein the air gap comprises a first region with a first width and level with the insulative columns and a second region with a second width between the first region and an upper surface of the semiconductor layer, wherein outer sidewalls of the insulative columns are exposed by the first region, and wherein the first width is greater than the second width.

3. The integrated device of claim 1, further comprising:
a third structure within the semiconductor layer, wherein the third structure comprises a different one of the sound port, the sealed cavity, or the proof mass than the first structure and the second structure, such that the sound port, the sealed cavity, and the proof mass are within the semiconductor layer.

4. The integrated device of claim 1, further comprising:
insulative columns within the semiconductor layer, wherein when one of the first structure or the second structure is the sound port, one or more arms overly the sound port and are separated from the semiconductor layer by the insulative columns.

5. The integrated device of claim 4, wherein the one or more arms are directly over the sound port and are spaced from one another by an additional air gap.

6. The integrated device of claim 1, wherein when one of the first structure or the second structure comprises the sealed cavity, the piezoelectric layer has an opening extending through the piezoelectric layer aligned with the sealed cavity.

7. The integrated device of claim 1, further comprising:
an insulative column within the semiconductor layer, wherein when one of the first structure or the second structure is the proof mass, the semiconductor layer comprises a first portion comprising the proof mass and a first arm attached to the proof mass and a second portion extending beneath the first portion, and the first portion is spaced from the second portion by the insulative column.

8. An integrated device, comprising:
a substrate having a first portion and a second portion;
a first sensor on the first portion of the substrate, the first sensor having a first moving structure being one of a first arm coupled to a proof mass, a cap overlying a sealed cavity, or one or more arms overlying a sound port extending through the substrate;
a second sensor on the second portion of the substrate, the second sensor having a second moving structure being one of the first arm coupled to the proof mass, the cap overlying a sealed cavity, or the one or more arms overlying the sound port extending through the substrate, the second moving structure being different from the first moving structure;
an application specific integrated circuit (ASIC) configured to receive first and second signals from the first sensor and the second sensor, respectively; and
a package surrounding the substrate and the ASIC, the package having a port connecting an inner region of the package to an ambient environment outside the package.

9. The integrated device of claim 8, wherein when the first moving structure is the one or more arms overlying the sound port extending through the substrate, the port of the package is directly beneath the sound port, directly coupling the sound port to the ambient environment outside the package.

10. The integrated device of claim 9, further comprising a semiconductor layer beneath the first moving structure and the second moving structure;
wherein when the first moving structure and the second moving structure are one or more arms overlying a sound port extending through the substrate and a cap overlying a sealed cavity, air gaps between the one or more arms and the semiconductor layer couple the ambient environment outside the package to the cap overlying the sealed cavity.

11. The integrated device of claim 9, wherein the port of the package and the sound port are centered on a first axis extending through the port of the package and the sound port, and wherein the second moving structure is offset from the port, such that the package extends between the ambient environment and the second moving structure.

12. The integrated device of claim 8, further comprising:
an air gap between the first moving structure and the second moving structure, the air gap comprising a first region having a first width directly between the first moving structure and the second moving structure and a second region beneath the first region having a second width, wherein the second width is greater than the first width.

13. The integrated device of claim 8, further comprising:
a semiconductor layer, wherein the first moving structure is level with the second moving structure and overlies the semiconductor layer; and
insulative columns coupling one of the first moving structure or the second moving structure to the semiconductor layer.

14. The integrated device of claim 8, further comprising a piezoelectric layer overlying the first moving structure and the second moving structure, wherein the piezoelectric layer is configured to convert a strain of the first moving structure and the second moving structure to the first and second signals, respectively.

15. A method of forming an integrated device, comprising:
forming a first sacrificial layer over a substrate, the substrate having a first side and a second side;
forming a first semiconductor layer having a first portion, a second portion, and a third portion on the first side of the substrate, wherein the third portion is directly over the first sacrificial layer;
forming a second sacrificial layer comprising multiple segments over the first portion, the second portion, and the third portion of the first semiconductor layer, wherein a first segment of the multiple segments is over the second portion of the first semiconductor layer;
forming a second semiconductor layer having a first portion, a second portion, and a third portion covering the second sacrificial layer, where the second portion of the second semiconductor layer covers the first segment of the second sacrificial layer, and wherein the first portion, the second portion, and the third portion of the second semiconductor layer respectively overly the first portion, the second portion, and the third portion of the first semiconductor layer;
forming a sealed cavity between the second semiconductor layer and the first semiconductor layer by removing the first segment of the second sacrificial layer;
forming a piezoelectric layer over the second semiconductor layer, the piezoelectric layer surrounding a plurality of wires;
forming a plurality of contacts coupled to the plurality of wires;
etching the piezoelectric layer and the second semiconductor layer to form air gaps separating the first portion, the second portion, and the third portion of the second semiconductor layer, exposing the second sacrificial layer;
etching the substrate and the first semiconductor layer from a second side of the substrate to delineate one or more structures within the first portion and the third portion of the first semiconductor layer, where the etching stops at the first sacrificial layer and the second sacrificial layer; and
etching the first sacrificial layer and the second sacrificial layer, removing portions of the first sacrificial layer and the second sacrificial layer exposed when forming the air gaps and delineating the one or more structures, expanding the air gaps between the first portion, the second portion, and the third portion of the second semiconductor layer.

16. The method of claim 15, wherein etching the piezoelectric layer and the second semiconductor layer to form an air gap further forms an additional air gap within the first portion of the second semiconductor layer;
wherein etching the substrate and the first semiconductor layer to delineate the one or more structures within the first portion of the first semiconductor layer comprises etching a sound port directly beneath the additional air gap; and
wherein when etching the second sacrificial layer, the second sacrificial layer between the additional air gap and the sound port is removed, connecting the additional air gap to the sound port.

17. The method of claim 15, wherein forming the sealed cavity further comprises:
etching a plurality of trenches through the second semiconductor layer, exposing the first segment of the second sacrificial layer;
etching the first segment, forming a cavity between the second portion of the first semiconductor layer and the second portion of the second semiconductor layer; and
filling the plurality of trenches, forming the sealed cavity between the second portion of the first semiconductor layer and the second portion of the second semiconductor layer.

18. The method of claim 15, further comprising:
wherein when etching the substrate and the first semiconductor layer to delineate one or more structures within the third portion of the first semiconductor layer, the first sacrificial layer covers a bottom surface of a proof mass delineated by the etch.

19. The method of claim 15, further comprising:
surrounding the substrate with a package comprising a port, wherein one of the one or more structures is a sound port, and wherein the port is centered on an axis extending through a center of the sound port within the first semiconductor layer.

20. The method of claim 15, wherein the one or more structures comprises a sound port in the first portion and a proof mass in the third portion of the first and second semiconductor layers, wherein the sealed cavity is directly between the sound port and the proof mass, wherein the sealed cavity, the sound port, and the proof mass are separated by the air gaps.
